(19) United States
(12) Patent Application Publication
(10) Pub. No.: US 2024/0219848 A1
(43) Pub. Date: Jul. 4, 2024

(54) EXTREME ULTRAVIOLET EXPOSURE APPARATUS INCLUDING A MASK STAGE

(71) Applicant: SAMSUNG ELECTRONICS CO., LTD., Suwon-si (KR)

(72) Inventors: Sanghwan LEE, Suwon-si (KR); Dohyung KIM, Suwon-si (KR); Jinhong PARK, Suwon-si (KR); Hachul SHIN, Suwon-si (KR); Seongchul HONG, Suwon-si (KR)

(21) Appl. No.: 18/519,497

(22) Filed: Nov. 27, 2023

(30) Foreign Application Priority Data
Dec. 29, 2022 (KR) 10-2022-0189739

(51) Int. Cl. G03F 7/00; G03F 1/42

(52) U.S. Cl. CPC G03F 7/7085; G03F 1/42; G03F 7/70175; G03F 7/702; G03F 7/70558; G03F 7/70716

(57) ABSTRACT

A mask stage, including a body, a support on a lower surface of the body including an attachable extreme ultraviolet mask, a fiducial mark on the lower surface of the body and spaced apart from the support, and a sensor area including a plurality of measurement sensors configured to measure an energy of a portion of extreme ultraviolet light incident on the body, wherein the sensor area is on the lower surface of the body and is spaced apart from the support in a scan direction of the extreme ultraviolet light, and the plurality of measurement sensors are spaced apart from one another in a direction perpendicular to the scan direction.

### CROSS-REFERENCE TO RELATED APPLICATION

Korean Patent Application No. 10-2022-0189739, filed on Dec. 29, 2022, in the Korean Intellectual Property Office, is incorporated by reference herein in its entirety.

### BACKGROUND

### 1. Field

An extreme ultraviolet exposure apparatus including a mask stage is disclosed.

### 2. Description of the Related Art

Recently, as the line widths of semiconductor circuits have gradually been miniaturized, light sources having shorter wavelengths are required.

### SUMMARY

Embodiments are directed to a mask stage, including a body, a support on a lower surface of the body including an attachable extreme ultraviolet mask, a fiducial mark on the lower surface of the body and spaced apart from the support, and a sensor area including a plurality of measurement sensors configured to measure an energy of a portion of extreme ultraviolet light incident on the body, wherein the sensor area is on the lower surface of the body and is spaced apart from the support in a scan direction of the extreme ultraviolet light, and the plurality of measurement sensors are spaced apart from one another in a direction perpendicular to the scan direction.

Embodiments are directed to an extreme ultraviolet exposure apparatus, including an extreme ultraviolet source, first optics configured to make an extreme ultraviolet light from the extreme ultraviolet source be incident upon an extreme ultraviolet mask, second optics configured to make the extreme ultraviolet light reflected by the extreme ultraviolet source be incident upon a wafer, a mask stage including a body, a support, and a sensor area, and a wafer stage on which the wafer, which is exposed, is placed, wherein the support is configured such that the extreme ultraviolet mask is attachable to and detachable from the support, and is on a lower surface of the body, the sensor area includes a plurality of measurement sensors configured to measure an energy of a portion of extreme ultraviolet light incident on the mask stage, the sensor area is on the lower surface of the body and is spaced apart from the support in a scan direction of the extreme ultraviolet light, and the plurality of measurement sensors are spaced apart from one another in a direction perpendicular to the scan direction.

Embodiments are directed to an extreme ultraviolet exposure apparatus, including an extreme ultraviolet source, first optics configured to make an extreme ultraviolet light from the extreme ultraviolet source be incident upon an extreme ultraviolet mask, second optics configured to make the extreme ultraviolet light reflected by the extreme ultraviolet source be incident upon a wafer, a mask stage including a body, a support, and a sensor area, a wafer stage on which the wafer, which is exposed, is placed, the wafer stage including a slit sensor, and a system configured to form a first profile and a second profile of the extreme ultraviolet light incident on the mask stage, wherein the slit sensor is configured to measure the first profile of the extreme ultraviolet light incident on the wafer stage, the support is configured such that the extreme ultraviolet mask is attachable to and detachable from the support, and is on a lower surface of the body, the sensor area includes a plurality of measurement sensors configured to measure an energy of a portion of extreme ultraviolet light incident on the mask stage, the sensor area is on the lower surface of the body and is spaced apart from the support in a scan direction of the extreme ultraviolet light, and the plurality of measurement sensors are spaced apart from one another in a direction perpendicular to the scan direction.

### BRIEF DESCRIPTION OF THE DRAWINGS

Features will become apparent to those of skill in the art by describing in detail exemplary embodiments with reference to the attached drawings in which:

FIG. 1 is a schematic perspective view showing a mask stage according to an example embodiment.

FIG. 2 is a top view showing the mask stage of FIG. 1.

FIG. 3 is a series of views showing movement of the mask stage of FIG. 1.

FIG. 4 is a graph showing values of a sensor of the mask stage of FIG. 1.

FIG. 5 is a top view showing a mask stage according to an example embodiment.

FIG. 6 is a diagram showing an EUV exposure apparatus according to an example embodiment.

FIG. 7 is a diagram showing an EUV exposure apparatus according to an example embodiment.

FIG. 8 is a graph showing measured values of a slit sensor of the EUV exposure apparatus of FIG. 7.

FIG. 9 is a diagram of an EUV exposure apparatus according to an example embodiment.

FIG. 10 is a graph showing measured values of first energy sensors of the EUV exposure apparatus of FIG. 9.

FIG. 11 is a diagram of an EUV exposure apparatus according to an example embodiment.

FIG. 12 is a diagram of an EUV exposure apparatus according to an example embodiment.

FIG. 13 is a graph showing feedback of a system of the EUV exposure apparatus of FIG. 12.

FIG. 14 is a graph showing the total energy of EUV light incident on a mask stage of FIG. 12.

### DETAILED DESCRIPTION

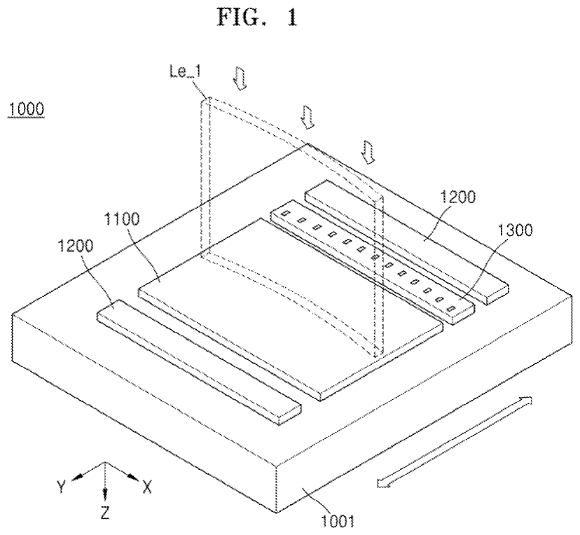

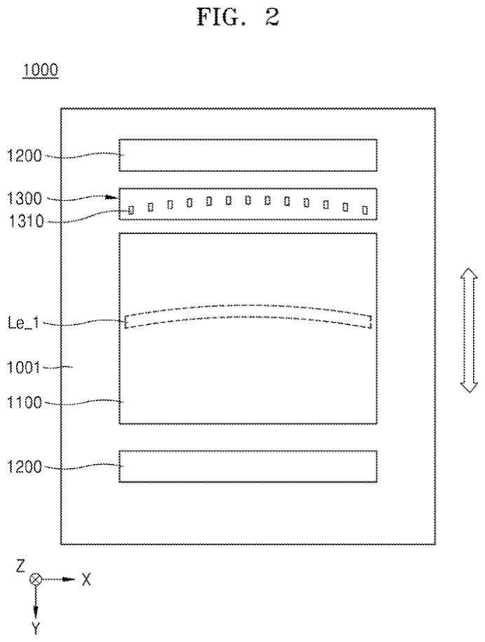

FIG. 1 is a schematic perspective view showing a mask stage according to an example embodiment. FIG. 2 is a top view showing the mask stage of FIG. 1. Referring to FIGS. 1 and 2, a mask stage 1000 may include a body 1001, a support 1100, fiducial marks 1200, and a sensor area 1300.

The mask stage 1000 may move in a scan direction of EUV light. The scan direction may be a direction perpendicular to a direction in which EUV light Le_1 incident on the mask stage 1000 extends. In other words, the scan direction may be a y-axis direction in FIG. 1. According to some embodiments, during a wafer exposure process or an exposure apparatus test, the mask stage 1000 may move in the y-axis direction to change an area irradiated with EUV light. In other words, as the mask stage 1000 moves in the y-axis direction, the EUV light may irradiate an EUV mask or the sensor area 1300.

The body 1001 of the mask stage 1000 may provide a space to which the support 1100, the fiducial marks 1200, and the sensor area 1300 may be attached. According to some embodiments, the support 1100, the fiducial marks 1200, and the sensor area 1300 may be attached to a lower surface of the body 1001.

The EUV mask may be attached to or detached from the support 1100 of the mask stage 1000. In other words, the EUV mask may be attached onto the support 1100. According to some embodiments, the support 1100 may attach and detach the EUV mask through an electrostatic force. In other words, the support 1100 may include an electrostatic chuck or a vacuum chuck. As used herein, the term “or” is not an exclusive term, e.g., “A or B” would include A, B, or A and B.

The fiducial marks 1200 of the mask stage 1000 may be spaced apart from the support 1100. According to some embodiments, the fiducial marks 1200 may be spaced apart from the support 1100 in the scan direction. According to some embodiments, the two fiducial marks 1200 may be spaced apart from each other in the scan direction with the support 1100 therebetween. When the EUV mask is attached to the mask stage 1000, the fiducial marks 1200 may serve as an alignment basis for the EUV mask. In other words, when the EUV mask is attached to the mask stage 1000, the EUV mask may be attached to an accurate position through the fiducial marks 1200. There may be one or a plurality of fiducial marks 1200.

The sensor area 1300 of the mask stage 1000 may be spaced apart from the support 1100 in the scan direction. According to some embodiments, the sensor area 1300 may be positioned between the support 1100 and one fiducial mark 1200. According to some embodiments, the fiducial mark 1200 may be spaced apart from one side of the support 1100 in the scan direction, and the sensor area 1300 may be spaced apart from the other side of the support 1100 in a direction opposite to the scan direction.

The sensor area 1300 may include a plurality of measurement sensors 1310. The plurality of measurement sensors 1310 may measure the energy of a portion of the EUV light Le_1 incident on the body 1001. In other words, the plurality of measurement sensors 1310 may be located in an area irradiated with the EUV light Le_1 incident on the mask stage 1000, and may measure the energy of the EUV light passing through the plurality of measurement sensors 1310. In other words, the plurality of measurement sensors 1310 may be located in a portion of a path of the EUV light Le_1 incident on the mask stage 1000, and may measure the energy of the EUV light at the location.

According to some embodiments, the sensor area 1300 may include about 10 to about 20 measurement sensors 1310. The measurement sensors 1310 may be located in the irradiation area of the EUV light Le_1 incident on the mask stage 1000. In other words, the about 10 to about 20 measurement sensors 1310 may be located in a width of the irradiation area of the EUV light Le_1 incident on the mask stage 1000.

According to some embodiments, the sensor area 1300 may include at least three measurement sensors 1310. The plurality of measurement sensors 1310 may be spaced apart from one another in the direction perpendicular to the scan direction. In other words, the plurality of measurement sensors 1310 may be spaced apart from one another in a direction in which EUV light extends. In other words, the plurality of measurement sensors 1310 may be spaced apart from one another in an x-axis direction. In other words, the plurality of measurement sensors 1310 may be spaced apart from one another in a width direction of the EUV light incident upon the mask stage 1000.

According to some embodiments, the EUV light Le_1 incident on the mask stage 1000) may have a curved slit shape. In other words, the EUV light Le_1 incident on the mask stage 1000 may have a slit shape having a large width compared to a length, and may have a shape having a curvature. In other words, the EUV light Le_1 incident on the mask stage 1000 may have a parabolic shape.

According to some embodiments, the plurality of measurement sensors 1310 may be arranged along the shape of the EUV light Le_1 incident on the mask stage 1000. In other words, the plurality of measurement sensors 1310 may be apart from one another to have the same shape as the shape of the EUV light Le_1 incident on the mask stage 1000. In other words, the shape in which the plurality of measurement sensors 1310 are arranged may be substantially the same as the shape in which EUV light beams are arranged.

According to some embodiments, the plurality of measurement sensors 1310 may be in a parabolic shape. In other words, the plurality of measurement sensors 1310 may be apart from one another in a curve shape. The shape of the EUV light Le_1 incident on the mask stage 1000 may be a curved slit shape, and the plurality of measurement sensors 1310 may be in the same curved slit shape as the shape of the EUV light Le_1 incident on the mask stage 1000.

The plurality of measurement sensors 1310 may measure the energies of different portions of the EUV light Le_1 incident on the mask stage 1000, respectively. In other words, the mask stage 1000 may measure the energy of each portion of the EUV light Le_1 incident on the mask stage 1000, through the plurality of measurement sensors 1310. A profile of the EUV light Le_1 incident on the mask stage 1000 may be formed through the energies of the portions of the EUV light respectively measured through the plurality of measurement sensors 1310.

According to some embodiments, the plurality of measurement sensors 1310 may be spaced apart from one another at regular intervals in the direction perpendicular to the scan direction. In other words, the plurality of measurement sensors 1310 may be spaced apart from one another at regular intervals in an extension direction of the EUV light. In other words, the plurality of measurement sensors 1310 may be arranged at regular intervals in an area irradiated with the EUV light Le_1 incident on the mask stage 1000. According to some embodiments, measurement sensors 1310 may be positioned at both ends of the width of the irradiation area of the EUV light Le_1 incident on the mask stage 1000, and a plurality of measurement sensors 1310 may be arranged at regular intervals between both ends of the width.

The plurality of measurement sensors 1310 may be arranged at regular intervals in the x-axis direction, and may measure a portion of the EUV light Le_1 incident on the mask stage 1000. Portions of the EUV light Le_1 incident on the mask stage 1000 respectively measured by the plurality of measurement sensors 1310 may be arranged at regular intervals. When a profile of the EUV light Le_1 incident on the mask stage 1000 is formed by measuring the irradiation areas of the EUV light Le_1 incident on the mask stage 1000 at equal intervals, an error with the actual EUV light may be small.

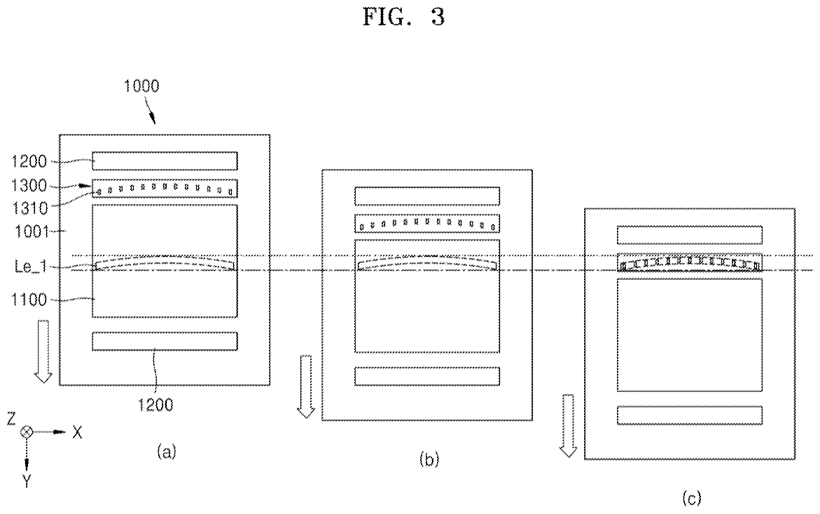

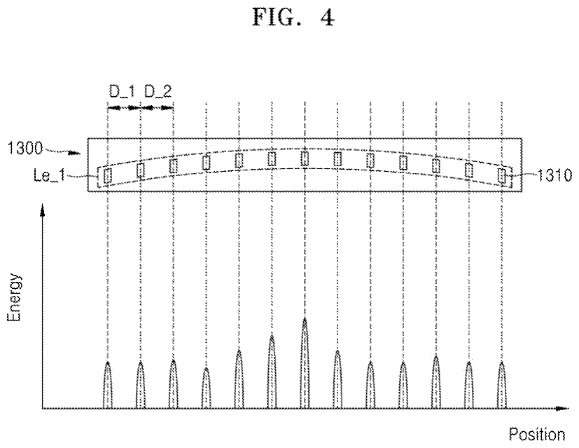

FIG. 3 is a series of views showing movement of the mask stage of FIG. 1. FIG. 4 is a graph showing values of a sensor of the mask stage of FIG. 1. FIGS. 3 and 4 schematically show a process of measuring EUV light by the sensor area 1300 according to movements of the mask stage 1000.

Referring to FIGS. 3 and 4, EUV light incident on the mask stage 1000 does not move toward an x-axis or y-axis, and, while the mask stage 1000 is moving in the y-axis direction, an area irradiated with the EUV light may vary.

According to some embodiments, FIGS. 3(a) and 3(b) may be a process of irradiating the EUV mask with the EUV light Le_1 incident on the mask stage 1000 during an exposure process. FIG. 3(c) may be a process of irradiating the EUV mask with the EUV light Le_1 incident on the mask stage 1000 during an exposure process. In other words, EUV light may scan the EUV mask while a wafer is being exposed, and EUV light may irradiate the sensor area 1300 while the wafer is not being exposed. In other words, the mask stage 1000 may be moved in the scan direction, that is, the y-axis direction, to irradiate a desired region of the mask stage 1000 with EUV light according to whether an exposure process is performed.

According to some embodiments, FIG. 4 is a graph showing measurement values measured by the sensor area 1300 according to positions, when EUV light is radiated onto the sensor area 1300. Referring to FIG. 4, the plurality of measurement sensors 1310 of the sensor area 1300 may be in the area irradiated with the EUV light. Each of the plurality of measurement sensors 1310 may measure the energy of a portion of the EUV light Le_1 incident on the mask stage. Accordingly, the mask stage 1000 may measure the energy of each location on the irradiation area of the EUV light through the measurement sensors 1310.

According to some embodiments, some of the plurality of measurement sensors 1310 may be located at both ends of the area irradiated with the EUV light, and the other measurement sensors 1310 may be arranged at regular intervals in the area irradiated with the EUV light. In other words, a distance between one measurement sensor and its adjacent measurement sensor in the x-axis direction may be a first distance D_1, and a distance between another measurement sensor and its adjacent measurement sensor in the x-axis direction may be a second distance D_2. The first distance D_1 and the second distance D_2 may be the same as each other. In other words, the plurality of measurement sensors 1310 may be spaced apart from one another at regular intervals and in the area irradiated with the EUV light.

The mask stage 1000 may be moved so that EUV light may be radiated onto the sensor area 1300 when an exposure apparatus is tested. In other words, the sensor area 1300 may not be in the irradiation area of the EUV light Le_1 incident on the mask stage during an exposure process. In other words, the sensor area 1300 may not affect a wafer quality during an exposure process.

The mask stage 1000 may measure the energy of the EUV light Le_1 incident on the mask stage, through the sensor area 1300, when an exposure apparatus is tested. Accordingly, an accurate total energy amount of the EUV light Le_1 incident on the mask stage may be obtained, and thus a determination as to which of first and second optics of the exposure apparatus has an error may be made.

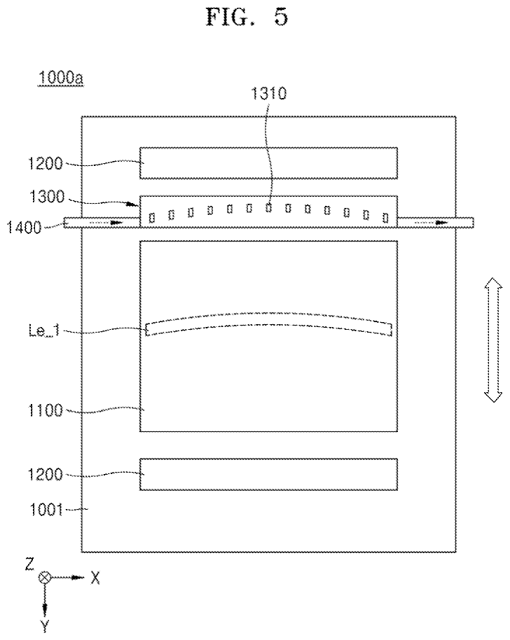

FIG. 5 is a top view showing a mask stage according to an example embodiment. Referring to FIG. 5, the mask stage 1000a may include the support 1100, the fiducial mark 1200, the sensor area 1300, and a cooling line 1400. Overlapping matters between the mask stage 1000a of FIG. 5 and the mask stage 1000 of FIG. 1 will be omitted, and differences therebetween will now be described.

The cooling line 1400 of the mask stage 1000a may supply a cooling fluid to the sensor area 1300. The cooling line 1400 may provide a path through which the cooling fluid may flow from one side of the sensor area 1300 to the other side thereof. In other words, the cooling fluid may flow from one side of the sensor area 1300 to the other side thereof through the cooling line 1400.

The cooling line 1400 may lower the temperature of the sensor area 1300. In other words, the cooling fluid may lower the temperature of the sensor area 1300 raised by the heat generated by the measurement sensor 1310 and the heat generated by the EUV light. A high temperature may affect the lifespan and measurement reliability of the measurement sensor 1310. Accordingly, the lifespan and measurement reliability of the measurement sensor 1310 may be improved by adjusting the temperature of the measurement sensor 1310 through the cooling line 1400.

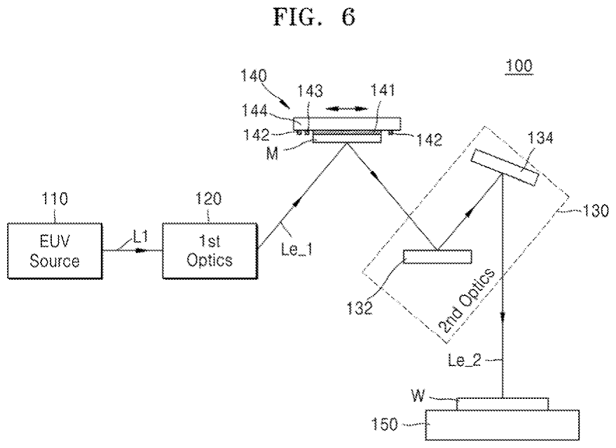

FIG. 6 is a diagram showing an EUV exposure apparatus according to an example embodiment. Referring to FIG. 6, the EUV exposure apparatus 100 may include an EUV source 110, first optics 120, second optics 130, a mask stage 140, and a wafer stage 150.

The EUV source 110 of the EUV exposure apparatus 100 may generate and output high energy density EUV light within a wavelength range of about 5 nm to about 50 nm. In an implementation, the EUV source 110 may generate and output high energy density EUV light of a wavelength of 13.5 nm. The EUV source 110 may be a plasma-based light source or a synchrotron radiation light source. The plasma-based light source refers to a light source that generates plasma and uses light emitted by the plasma. Examples of the plasma-based light source may include a laser-produced plasma (LPP) light source or a discharge-produced plasma (DPP) light source.

In the EUV exposure apparatus 100 according to the present embodiment, the EUV source 110 may be, e.g., a plasma-based light source. A plasma-based light source may include a condensing mirror such as an elliptical mirror or spherical mirror for concentrating EUV light, in order to increase the energy density of illumination light incident upon the first optics 120.

The first optics 120 of the EUV exposure apparatus 100 may include a plurality of mirrors. In an implementation, in the EUV exposure apparatus 100 according to the present embodiment, the first optics 120 may include two or three mirrors or may include more than three mirrors. The first optics 120 may transmit EUV light from the EUV source 110 to an EUV mask M. In an implementation, the EUV light from the EUV source 110 may be incident upon the EUV mask M on the mask stage 140 through reflection by the mirrors in the first optics 120. The first optics 120 may make the EUV light into a curved slit shape and make the EUV light having the curved slit shape be incident upon the EUV mask M.

The second optics 130 of the EUV exposure apparatus 100 may include a plurality of mirrors. In FIG. 6, the second optics 130 are illustrated as including two mirrors, namely, a first mirror 132 and a second mirror 134. In an implementation, in the EUV exposure apparatus 100 the second optics 130 may include four to eight mirrors.

The EUV mask M may be on the mask stage 140 of the EUV exposure apparatus 100. The mask stage 140 may move in x- and y-directions on a x-y plane and in a z-direction perpendicular to the x-y plane, while the EUV mask M is being disposed.

The mask stage 140 may include a body 144, a support 141, and a sensor area 143. According to some embodiments, the mask stage 140 may include a fiducial mark 142. The mask stage 140 may move in the scan direction, namely, the y-axis direction. The EUV mask M may be attached to or detached from the support 141 of the mask stage 140.

The sensor area 143 may include a plurality of measurement sensors. The plurality of measurement sensors may measure the energy of a portion of the EUV light Le_1 incident on the mask stage 140. The support 141 and the sensor area 143 may be spaced apart from each other in the scan direction. The plurality of measurement sensors may be spaced apart from one another in an extension direction of EUV light.

According to some embodiments, the EUV light Le_1 incident on the mask stage 140 may have a curved slit shape. According to some embodiments, the plurality of measurement sensors of the sensor area 143 may be apart from each other in the same shape as that of the EUV light. In other words, the plurality of measurement sensors may be apart from one another to form a curve shape.

According to some embodiments, the mask stage 140 may include the mask stage 1000 of FIG. 1 and the mask stage 1000a of FIG. 5. The EUV mask M may be a reflective mask having a reflective region and a non-reflective or intermediate reflective region. The EUV mask M may include a reflective multi-layer for reflecting EUV on a substrate formed of a low thermal expansion coefficient material (LTEM), such as quartz, and an absorption layer pattern on the reflective multi-layer. The reflective multi-layer may have, e.g., a structure in which a molybdenum (Mo) layer and a silicon (Si) layer are alternately stacked in several tens or more layers. The absorption layer may be, e.g., TaN, TaNO, TaBO, Ni, Au, Ag, C, Te, Pt, Pd, or Cr. The portion of the absorbing layer may correspond to the aforementioned non-reflective or intermediate reflective area.

The EUV mask M may reflect the EUV light incident through the first optics 120 and make the EUV light be incident upon the second optics 130. The EUV mask M may reflect the EUV light from the first optics so that the EUV light is structured according to a pattern shape composed of the reflective multi-layer and the absorption layer on the substrate, and may make the reflected EUV light enter the second optics 130. The EUV light may be structured to include at least second-order diffracted light, based on a pattern on the EUV mask M. The structured EUV light may be incident upon the second optics 130 while retaining information of the pattern shape on the EUV mask M and may be projected onto an EUV exposure target W through the second optics 130 so that an image corresponding to the pattern shape is formed. The EUV exposure target W may be a substrate including a semiconductor material such as silicon, e.g., a wafer. Unless otherwise specified, the EUV exposure object W and the wafer are used as the same concept.

The EUV exposure target W, e.g., a wafer, may be on the wafer stage 150 of the EUV exposure apparatus 100. The wafer stage 150 may move in the x- and y-directions on the x-y plane, and may move in the z-direction perpendicular to the x-y plane. The wafer stage 150 may rotate on the x-y plane with respect to a z axis, or may rotate on the y-z plane or the x-z plane with respect to any one axis on the x-y plane, e.g., the x-axis or the y-axis. Due to the movement of the wafer stage 150, the EUV exposure target W may be moved in the x, y, or z direction, and may also be rotated about the x, y, or z axis.

As described above, the second optics 130 may transmit the EUV light reflected by the EUV mask M to the EUV exposure target W through reflection by the mirrors.

The EUV exposure apparatus 100 may measure the energy of a portion of the EUV light Le_1 incident on the mask stage 140, through the sensor area 143. In other words, the EUV exposure apparatus 100 may measure the energy of each portion of the EUV light Le_1 incident on the mask stage 140, through a plurality of measurement sensors. A profile of the EUV light Le_1 incident on the mask stage 140 may be formed through the energies of the portions of the EUV light Le_1 respectively measured through the plurality of measurement sensors.

The EUV exposure apparatus 100 may measure the energy of the EUV light Le_1 incident on the mask stage 140, through the sensor area 143 during exposure apparatus testing. Accordingly, the accurate total energy amount of the EUV light Le_1 incident on the mask stage 140 may be obtained, and thus a determination as to which of the first and second optics 120 and 130 of the EUV exposure apparatus 100 has an error may be made.

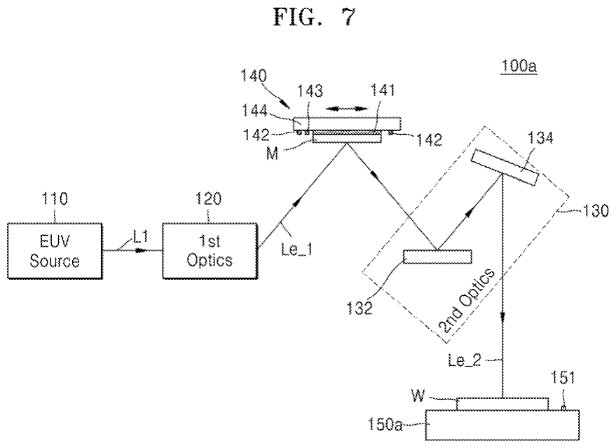

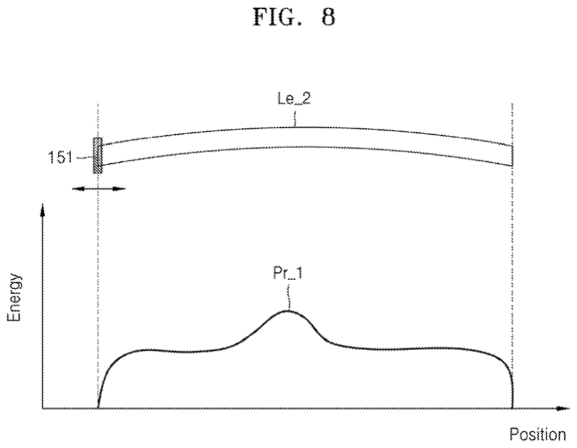

FIG. 7 is a diagram showing an EUV exposure apparatus according to an example embodiment. FIG. 8 is a graph showing measured values of a slit sensor of the EUV exposure apparatus of FIG. 7.

Referring to FIGS. 7 and 8, the EUV exposure apparatus 100a may include an EUV source 110, first optics 120, second optics 130, a mask stage 140, and a wafer stage 150a. Overlapping matters between the EUV exposure apparatus 100a of FIG. 7 and the EUV exposure apparatus 100 of FIG. 6 will be omitted, and differences therebetween will now be described.

The wafer stage 150a of the EUV exposure apparatus 100a may further include the slit sensor 151. The slit sensor 151 may be spaced apart from the EUV exposure target W. The slit sensor 151 may measure the energy of EUV light Le_2 incident on the wafer stage 150a.

The slit sensor 151 may be attached to the wafer stage 150a and move as the wafer stage 150a moves. In other words, the slit sensor 151 may move along the wafer stage 150a and continuously measure the energy of the EUV light Le_2 incident on the wafer stage 150a, thereby measuring a first profile Pr_1 of the EUV light Le_2 incident on the wafer stage 150a.

According to some embodiments, the wafer stage 150a may move in the x-axis, y-axis, and z-axis directions. In other words, the wafer stage 150a may move in the scan direction and in the direction perpendicular to the scan direction. Accordingly, the slit sensor 151 attached to the wafer stage 150a may also move in the x-axis, y-axis, and z-axis directions. In other words, as the wafer stage 150a moves, the slit sensor 151 may move in a direction that intersects a traveling direction of the EUV light Le_2 incident on the wafer stage 150a.

The slit sensor 151 may measure the first profile Pr_1 of the EUV light Le_2 incident on the wafer stage 150a. The slit sensor 151 may move over an irradiation area of the EUV light Le_2 incident on the wafer stage 150a to measure the first profile Pr_1 of the EUV light Le_2. In other words, the slit sensor 151 may consecutively measure the energy of the EUV light Le_2 incident on the wafer stage 150a. In other words, the slit sensor 151 may represent the energy of EUV light in the shape of a continuous profile.

The EUV exposure apparatus 100a may measure the first profile Pr_1 of the EUV light Le_2 incident on the wafer stage 150a before and after an exposure process to thereby measure the accurate total energy amount of the EUV light Le_2 incident on the wafer stage 150a. In other words, the EUV exposure apparatus 100a may precisely measure the EUV light Le_2 incident on the wafer stage 150a through the slit sensor 151, thereby improving the quality of the exposure process.

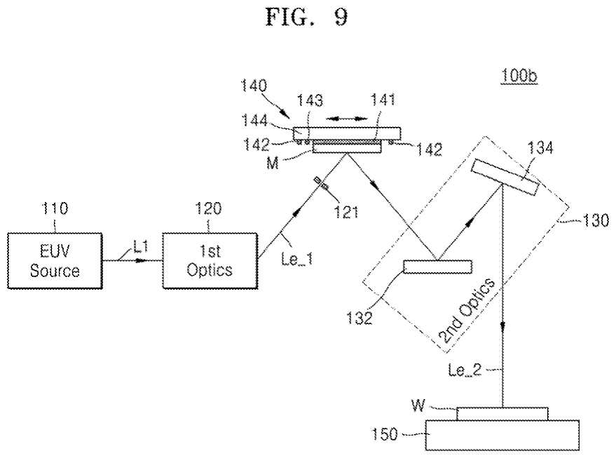

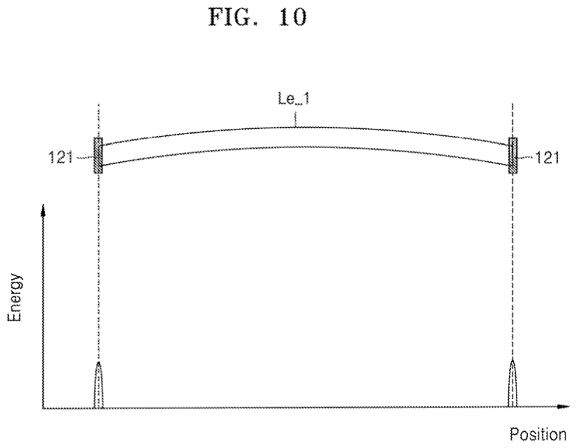

FIG. 9 is a diagram of an EUV exposure apparatus according to an example embodiment. FIG. 10 is a graph showing measured values of first energy sensors of the EUV exposure apparatus of FIG. 9.

Referring to FIGS. 9 and 10, the EUV exposure apparatus 100b may include an EUV source 110, first optics 120, the first energy sensors 121, the second optics 130, a mask stage 140, and a wafer stage 150. Overlapping matters between the EUV exposure apparatus 100b of FIG. 9 and the EUV exposure apparatus 100 of FIG. 6 will be omitted, and differences therebetween will now be described.

The first energy sensors 121 of the EUV exposure apparatus 100b may measure the energy of the EUV light Le_1 incident on the mask stage 140. The first energy sensors 121 may be located on both sides of the EUV light Le_1 incident on the mask stage 140 to measure the energies of the both ends of the EUV light Le_2.

According to some embodiments, the first energy sensors 121 may be located on both sides of the EUV light Le_1 incident on the mask stage 140. The first energy sensors 121 may be spaced apart from the mask stage 140. According to some embodiments, the first energy sensors 121 may be attached to a area where the first optics 120 are located, to thereby measure the energy of the EUV light Le_1 incident on the mask stage 140.

In other words, because the first energy sensors 121 may be spaced apart from the mask stage 140, the first energy sensors 121 may move independently of a movement of the mask stage 140. In other words, even when the mask stage 140 moves, the position of the first energy sensors 121 may not change. Accordingly, the first energy sensors 121 may measure the EUV light Le_1 incident on the mask stage 140, regardless of the movement of the mask stage 140.

In other words, unlike the sensor area 143, the first energy sensors 121 may always measure the EUV light Le_1 incident on the mask stage 140. The first energy sensors 121 may obtain the energy of the EUV light Le_1 incident on the mask stage 140 during an exposure process.

Because the EUV exposure apparatus 100b may be able to obtain the energy of the EUV light Le_1 incident on the mask stage 140 during the exposure process by using the first energy sensors 121, the EUV exposure apparatus 100b may control the amount of energy of the EUV light L1 generated by the EUV source 110.

Because the first energy sensors 121 of the EUV exposure apparatus 100b may be located on both sides of the EUV light Le_1 incident on the mask stage 140, the first energy sensors 121 may not affect the quality of the exposure process.

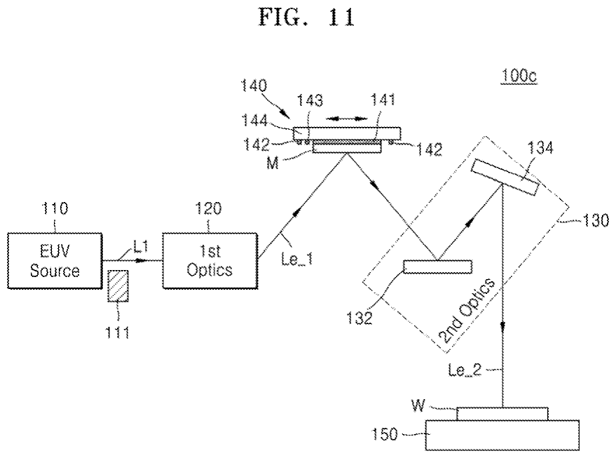

FIG. 11 is a diagram of an EUV exposure apparatus according to an example embodiment. Referring to FIG. 11, the EUV exposure apparatus 100c may include an EUV source 110, a second energy sensor 111, first optics 120, second optics 130, a mask stage 140, and a wafer stage 150. Overlapping matters between the EUV exposure apparatus 100c of FIG. 11 and the EUV exposure apparatus 100 of FIG. 6 will be omitted, and differences therebetween will now be described.

The second energy sensor 111 of the EUV exposure apparatus 100c may measure the total energy of EUV light L1 generated by the EUV source 110. In other words, the second energy sensor 111 may measure the energy of the EUV light L1 generated by the EUV source 110 and not yet incident upon the first optics 120. In other words, the second energy sensor 111 may be attached to an area where the EUV source 110 is located and may measure the energy of the EUV light L1 emitted by the EUV source 110.

According to some embodiments, the EUV exposure apparatus 100c may include the second energy sensor 111, the sensor area 143 of the mask stage 140, and the slit sensor 151 (see FIG. 7) of the wafer stage 150. The EUV exposure apparatus 100c may measure the energies of EUV light in the EUV source 110, the mask stage 140, and the wafer stage 150 by using the second energy sensor 111, the sensor area 143, and the slit sensor 151.

The EUV exposure apparatus 100c may control the energy of the EUV light L1 generated by the EUV source 110, through total energy of EUV light generated by the EUV source 110 measured through the second energy sensor 111 and an energy level of the EUV light Le_1 incident upon the mask stage 140 measured through the first energy sensors 121 of FIG. 9.

The EUV exposure apparatus 100c may accurately measure a total energy of EUV light L1 in the EUV source 110, the mask stage 140, and the wafer stage 150 by using the second energy sensor 111, the sensor area 143, and the slit sensor 151. Accordingly, a determination as to which configuration of the EUV source 110, the first optics 120, and the second optics 130 has an error may be made during an exposure apparatus test.

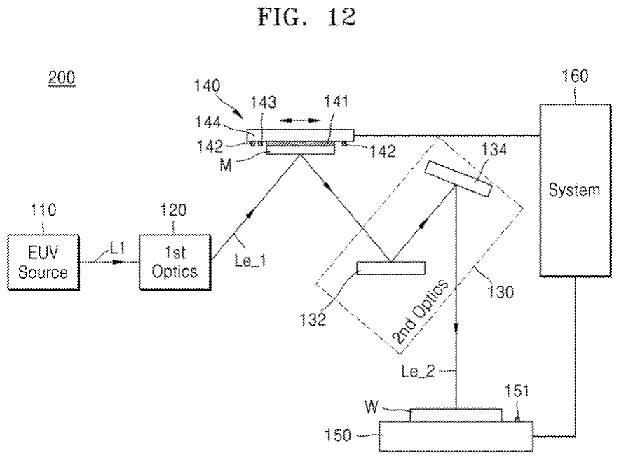

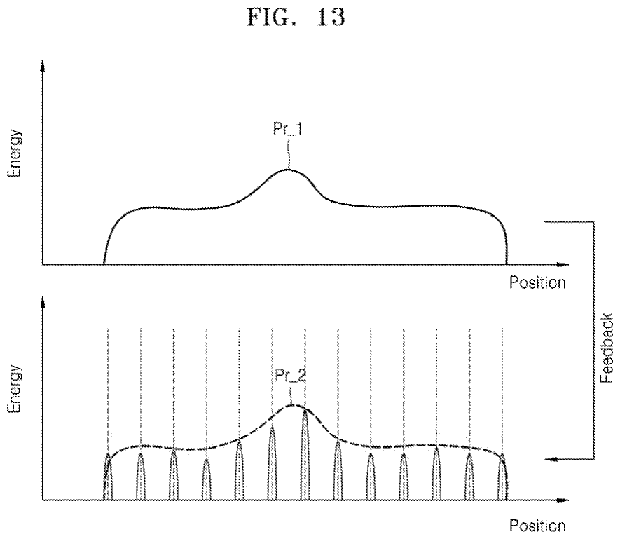

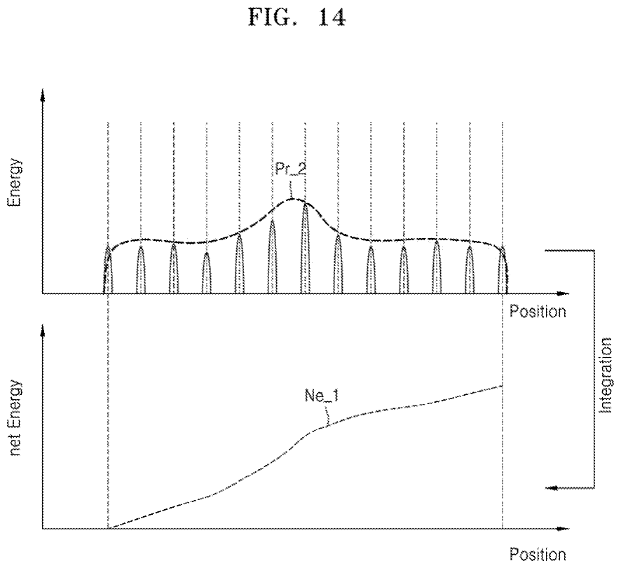

FIG. 12 is a diagram of an EUV exposure apparatus according to an example embodiment. FIG. 13 is a graph showing feedback of a system of the EUV exposure apparatus of FIG. 12. FIG. 14 is a graph showing the total energy of EUV light incident on a mask stage of FIG. 12. Referring to FIG. 12 through 14, the EUV exposure apparatus 200 may include an EUV source 110, first optics 120, second optics 130, the mask stage 140, a wafer stage 150, and a system 160. Overlapping matters between the EUV exposure apparatus 200 of FIG. 12 and the EUV exposure apparatus 100 of FIG. 6 will be omitted, and differences therebetween will now be described.

The EUV source 110 of the EUV exposure apparatus 200 may generate and output high energy density EUV light within a wavelength range of about 5 nm to about 50 nm. In an implementation, the EUV source 110 may generate and output high energy density EUV light of a wavelength of 13.5 nm. According to some embodiments, the EUV source 110 may include the EUV source 110 of FIG. 6.

The first optics 120 of the EUV exposure apparatus 200 may make EUV light from an EUV source be incident upon an EUV mask. The first optics 120 may include a plurality of mirrors. In an implementation, in the EUV exposure apparatus 200 according to the present embodiment, the first optics 120 may include two or three mirrors. According to some embodiments, the first optics 120 may include the first optics 120 of FIG. 6.

The second optics 130 of the EUV exposure apparatus 200 may make EUV light from the EUV mask be incident upon a wafer. The second optics 130 may include a plurality of mirrors. In FIG. 12, the second optics 130 are illustrated as including two mirrors, namely, a first mirror 132 and a second mirror 134.

The mask stage 140 of the EUV exposure apparatus 200 may include a support 141 and a sensor area 143. The support 141 may attach and detach the EUV mask. The sensor area 143 may include a plurality of measurement sensors. According to some embodiments, the mask stage 140 may include a fiducial mark 142.

The sensor area 143 may include a plurality of measurement sensors. The plurality of measurement sensors may measure the energy of a portion of the EUV light Le_1 incident on the mask stage 140. The support 141 and the sensor area 143 may be spaced apart from each other in the scan direction. The plurality of measurement sensors may be spaced apart from one another in an extension direction of EUV light. According to some embodiments, the plurality of measurement sensors 1310 may be apart from each other in a parabolic shape.

According to some embodiments, the sensor area 143 may include about 10 to about 20 measurement sensors. The plurality of measurement sensors may be located within the irradiation area of the EUV light Le_1 incident on the mask stage 140. In other words, the about 10 to about 20 measurement sensors may be located in a width of the irradiation area of the EUV light Le_1 incident on the mask stage 140.

According to some embodiments, the plurality of measurement sensors may be spaced apart from one another at regular intervals in the direction perpendicular to the scan direction. In other words, the plurality of measurement sensors may be spaced apart from one another at regular intervals. In other words, the plurality of measurement sensors may be arranged at regular intervals in the irradiation area of the EUV light Le_1 incident on the mask stage 140.

According to some embodiments, the mask stage 140 may include the mask stage 1000 of FIG. 1 and the mask stage 1000a of FIG. 5.

An EUV exposure target W, e.g., a wafer, may be on the wafer stage 150 of the EUV exposure apparatus 200. The wafer stage 150 may move in the x- and y-directions on the x-y plane, and may move in the z-direction perpendicular to the x-y plane. According to some embodiments, the wafer stage 150 may include the wafer stage 150 of FIG. 6.

The system 160 of the EUV exposure apparatus 200 may form a second profile Pr_2 of the EUV light Le_1 incident on the mask stage 140. The system 160 may form the second profile Pr_2 of the EUV light Le_1 incident on the mask stage 140, based on a measured value obtained by the sensor area 143 of the mask stage 140 and a measured value obtained by the slit sensor 151 of the wafer stage 150. In other words, based on the first profile Pr_1 of the EUV light Le_2 incident on the wafer stage 150 measured by the slit sensor 151, the system 160 may form the second profile Pr_2 of the EUV light Le_1 incident on the mask stage 140.

The EUV light Le_2 incident on the wafer stage 150 and the EUV light Le_1 incident on the mask stage 140 may have different energy levels and have the same profile. In other words, based on the first profile Pr_1 measured by the slit sensor 151 and the energy level of the EUV light Le_1 incident on the mask stage 140 measured by the sensor area 143, the system 160 may form the second profile Pr_2 of the EUV light Le_1 incident on the mask stage 140.

Referring to FIG. 13, based on the first profile Pr_1 measured by the slit sensor 151 and the energy of a portion of the EUV light Le_1 incident on the mask stage 140 measured by the sensor area 143, the system 160 may form the second profile Pr_2 of the EUV light Le_1 incident on the mask stage 140. The shape of the second profile Pr_2 may be similar to that of the first profile Pr_1, but the amount of energy of the second profile Pr_2 may be similar to the measured value obtained by the sensor area 143.

Based on the second profile Pr_2 of the EUV light Le_1 incident on the wafer stage 150, the system 160 may calculate the total energy of the EUV light Le_1 incident on the mask stage 140. In other words, the system 160 may calculate a total energy Ne_1 of the EUV light Le_1 incident on the mask stage 140, by integrating the second profile Pr_2. Accordingly, the system 160 may precisely calculate the total energy of the EUV light Le_1 incident on the mask stage 140.

The second profile Pr_2 may continuously represent the energy of the irradiation area of the EUV light Le_1 incident on the mask stage 140. In other words, the second profile Pr_2 may represent a total energy value of the irradiation area of the EUV light Le_1 incident on the mask stage 140, rather than an energy value of a portion of the irradiation area of the EUV light Le_1 incident on the mask stage 140 measured by the sensor area 143.

The system 160 may calculate the total energy Ne_1 of the EUV light Le_1 incident on the mask stage 140, by integration according to positions of the second profile Pr_2. The total energy Ne_1 of the EUV light Le_1 incident on the mask stage 140 calculated through the second profile Pr_2 may be substantially the same as the total energy Ne_1 of the EUV light Le_1 actually incident on the mask stage 140.

The EUV exposure apparatus 200 may determine which optics among the first optics 120 and the second optics 130 have an error, through the total energy Ne_1 of the EUV light Le_1 incident on the mask stage 140 calculated by the system 160.

When a difference between the total energy Ne_1 of the EUV light Le_1 incident on the mask stage 140 of the EUV exposure apparatus 200 under test and a reference value exceeds an error range, the first optics 120 may have an error. When the difference between the total energy Ne_1 of the EUV light Le_1 incident on the mask stage 140 of the EUV exposure apparatus 200 under test and the reference value is within the error range and a difference between a total energy of the EUV light Le_2 incident on the wafer stage 150 and a reference value exceeds an error range, the second optics 130 may have an error.

Because the EUV exposure apparatus 200 may determine optics in which an error has occurred, maintenance time and costs for repairing the EUV exposure apparatus 200 may be reduced. In other words, the total energy Ne_1 of the EUV light Le_1 incident on the mask stage 140 may be calculated through the sensor area 143, the slit sensor 151, and the system 160, and thus, when the EUV exposure apparatus 200 is tested, a faulty configuration may be ascertained in detail and may be replaced. Accordingly, costs and time incurred to repair the EUV exposure apparatus 200 may be reduced.

By way of summation and review, a mask stage and an EUV exposure apparatus both capable of measuring energy of EUV light is disclosed. In an implementation, EUV light may be used as an exposure light source. Due to the absorption characteristics of EUV light, a reflective EUV mask may be used in an EUV exposure process. In addition, illumination optics for transmitting EUV light to an EUV mask and projection optics for projecting EUV light reflected by the EUV mask onto an exposure target may include a plurality of mirrors. As the difficulty of the exposure process gradually increases, small errors in an EUV mask or mirrors may cause serious errors in pattern formation on a wafer.

A mask stage and an EUV exposure apparatus both capable of accurately measuring the energy of extreme ultraviolet (EUV) light incident on a mask is disclosed. An EUV exposure apparatus capable of determining which optics among illumination optics and projection optics has an error is disclosed.

Example embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, or elements described in connection with a particular embodiment may be used singly or in combination with features, characteristics, or elements described in connection with other embodiments unless otherwise specifically indicated. Accordingly, it will be understood by those of skill in the art that various changes in form and details may be made.

What is claimed is:

1. A mask stage, comprising:
a body;
a support on a lower surface of the body, the support including an attachable extreme ultraviolet mask;
a fiducial mark on the lower surface of the body and spaced apart from the support; and
a sensor area including a plurality of measurement sensors configured to measure an energy of a portion of extreme ultraviolet light incident on the body,
wherein:
the sensor area is on the lower surface of the body and is spaced apart from the support in a scan direction of the extreme ultraviolet light, and
the plurality of measurement sensors are spaced apart from one another in a direction perpendicular to the scan direction.

2. The mask stage as claimed in claim 1, wherein:
the extreme ultraviolet light is in a curved slit shape, and
the plurality of measurement sensors are spaced apart from one another in a same shape of the extreme ultraviolet light.

3. The mask stage as claimed in claim 1, wherein the plurality of measurement sensors are in a parabolic shape.

4. The mask stage as claimed in claim 1, wherein the sensor area is located between the fiducial mark and the support.

5. The mask stage as claimed in claim 1, wherein the plurality of measurement sensors are spaced apart from one another at regular intervals.

6. The mask stage as claimed in claim 1, wherein the support is configured to attach and detach the extreme ultraviolet mask through an electrostatic force.

7. The mask stage as claimed in claim 1, further comprising a cooling line configured to supply cooling fluid to the sensor area.

8. The mask stage as claimed in claim 1, wherein the sensor area includes 10 to 20 measurement sensors.

9. An extreme ultraviolet exposure apparatus, comprising:
an extreme ultraviolet source;
first optics configured to make an extreme ultraviolet light from the extreme ultraviolet source be incident upon an extreme ultraviolet mask;
second optics configured to make the extreme ultraviolet light reflected by the extreme ultraviolet mask be incident upon a wafer;
a mask stage including a body, a support, and a sensor area; and
a wafer stage on which the wafer, which is exposed, is placed,
wherein:
the support is configured such that the extreme ultraviolet mask is attachable to and detachable from the support, and is on a lower surface of the body,
the sensor area includes a plurality of measurement sensors configured to measure an energy of a portion of extreme ultraviolet light incident on the mask stage,
the sensor area is on the lower surface of the body and is spaced apart from the support in a scan direction of the extreme ultraviolet light, and
the plurality of measurement sensors are spaced apart from one another in a direction perpendicular to the scan direction.

10. The extreme ultraviolet exposure apparatus as claimed in claim 9, wherein the wafer stage includes a slit sensor configured to measure a first profile of extreme ultraviolet light incident on the wafer stage.

11. The extreme ultraviolet exposure apparatus as claimed in claim 10, wherein the slit sensor is configured to move along with movement of the wafer stage.

12. The extreme ultraviolet exposure apparatus as claimed in claim 10, wherein the slit sensor is able to continuously measure an energy of the extreme ultraviolet light incident on the wafer stage.

13. The extreme ultraviolet exposure apparatus as claimed in claim 9, further comprising a first energy sensor configured to measure energy of both sides of the extreme ultraviolet light incident on the mask stage, wherein the first energy sensor is positioned at the sides of the extreme ultraviolet light incident on the mask stage.

14. The extreme ultraviolet exposure apparatus as claimed in claim 13, wherein the first energy sensor is spaced apart from the mask stage.

15. The extreme ultraviolet exposure apparatus as claimed in claim 9, further comprising a second energy sensor configured to measure a total energy of the extreme ultraviolet light generated by the extreme ultraviolet source.

16. The extreme ultraviolet exposure apparatus as claimed in claim 9, wherein:
the extreme ultraviolet light incident on the mask stage has a curved slit shape, and
the plurality of measurement sensors are spaced apart from one another in a same shape of the extreme ultraviolet light.

17. An extreme ultraviolet exposure apparatus, comprising:
an extreme ultraviolet source;
first optics configured to make an extreme ultraviolet light from the extreme ultraviolet source be incident upon an extreme ultraviolet mask;
second optics configured to make the extreme ultraviolet light reflected by the extreme ultraviolet mask be incident upon a wafer;
a mask stage including a body, a support, and a sensor area;
a wafer stage on which the wafer, which is exposed, is placed, the wafer stage including a slit sensor; and
a system configured to form a second profile of the extreme ultraviolet light incident on the mask stage,
wherein:
the slit sensor is configured to measure a first profile of the extreme ultraviolet light incident on the wafer stage,
the support is configured such that the extreme ultraviolet mask is attachable to and detachable from the support, and is on a lower surface of the body,
the sensor area includes a plurality of measurement sensors configured to measure an energy of a portion of extreme ultraviolet light incident on the mask stage,
the sensor area is on the lower surface of the body and is spaced apart from the support in a scan direction of the extreme ultraviolet light, and
the plurality of measurement sensors are spaced apart from one another in a direction perpendicular to the scan direction.

18. The extreme ultraviolet exposure apparatus as claimed in claim 17, wherein the system is configured to form the second profile of extreme ultraviolet light incident on the mask stage, based on the first profile and the energy of the portion of the extreme ultraviolet light measured by the sensor area.

19. The extreme ultraviolet exposure apparatus as claimed in claim 18, wherein the system is configured to calculate a total energy of the extreme ultraviolet light incident on the mask stage, based on the second profile of extreme ultraviolet light incident on the mask stage.

20. The extreme ultraviolet exposure apparatus as claimed in claim 17, wherein:
the sensor area of the mask stage includes 10 to 20 measurement sensors, and
the plurality of measurement sensors are spaced apart from one another at equal intervals in a direction of the extreme ultraviolet light incident on the mask stage and are in a parabolic shape.
